(19) United States
(12) Patent Application Publication
(10) Pub. No.: US 2025/0386501 A1
(43) Pub. Date: Dec. 18, 2025

(54) SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Soo Jin Kim, Suwon-si (KR); Younghwi Yang, Suwon-si (KR); Seung Jae Baik, Suwon-si (KR); Woojae Jang, Suwon-si (KR)

(21) Appl. No.: 19/004,083

(22) Filed: Dec. 27, 2024

(30) Foreign Application Priority Data
Jun. 18, 2024 (KR) 10-2024-0078861

(51) Int. Cl. H10B 43/27; G11C 16/04; H01L 25/07; H10B 43/10; H10B 43/35; H10B 43/40; H10B 80/00

(52) U.S. Cl. CPC H10B 43/27; G11C 16/0483; H01L 25/071; H10B 43/10; H10B 43/35; H10B 43/40; H10B 80/00; H01L 2225/06506

(57) ABSTRACT

A semiconductor memory device includes a substrate, a mold structure including a plurality of gate electrodes and a plurality of mold insulating layers, alternatively stacked on the substrate, and a channel structure extending through the mold structure, in which the channel structure may include an information storage circuit, a light emitting circuit, and a first metal layer, sequentially stacked on side surfaces of the plurality of gate electrodes, the channel structure may further include a photodetection circuit disposed on the first metal layer, and the photodetection circuit may be configured to detect light emitted from the light emitting circuit, in which a level of the light detected by the photodetection circuit is indicative of a memory state of the information storage circuit.

### CROSS-REFERENCE TO RELATED APPLICATION

This application claims priority to Korean Patent Application No. 10-2024-0078861, filed in the Korean Intellectual Property Office on Jun. 18, 2024, the entire contents of which are hereby incorporated by reference.

### BACKGROUND

There is a need for a semiconductor memory device capable of storing high-capacity data in an electronic system that requires data storage. Accordingly, ways to increase the data storage capacity of the semiconductor memory devices are being studied. For example, as one of the methods for increasing the data storage capacity of the semiconductor device, a semiconductor device has been proposed, which includes three-dimensional arrangement of memory cells instead of two-dimensional arrangement of memory cells.

As the capacity and integration density of the semiconductor devices increase, power consumption and heat generation of semiconductor devices can also increase. In particular, when a read operation is performed in a semiconductor memory device, read voltage is applied to not only the target cell, but also the other cells, resulting in a problem of increased power consumption and also reduced reliability of the cell reduced due to frequent voltage application. This may cause performance degradation and damage of the semiconductor device.

### SUMMARY

In general, the present disclosure is directed toward a semiconductor memory device and an electronic system including the same.

According to some implementations, the present disclosure is directed to a semiconductor memory device that includes a substrate, a mold structure including a plurality of gate electrodes and a plurality of mold insulating layers, alternatively stacked on the substrate, and a channel structure extending through the mold structure, wherein the channel structure may include a an information storage circuit, a light emitting device, and a first metal layer, sequentially stacked on side surfaces of the plurality of gate electrodes, the channel structure may further include a photodetection circuit disposed on the first metal layer, and the photodetection circuit may be configured to detect light emitted from the light emitting circuit.

According to some implementations, the present disclosure is directed to a semiconductor memory device that includes a substrate, a mold structure including a plurality of gate electrodes and a plurality of mold insulating layers, alternatively stacked on the substrate, and a channel structure extending through the mold structure, wherein the channel structure may include an information storage circuit, a light emitting circuit, and a metal layer, sequentially stacked on side surfaces of the plurality of gate electrodes.

According to some implementations, the present disclosure is directed to an electronic system that includes a main substrate, a semiconductor memory device on the main substrate, and a controller electrically connected to the semiconductor memory device on the main substrate, wherein the semiconductor memory device may include a cell substrate, a mold structure including a plurality of gate electrodes and a plurality of mold insulating layers, alternatively stacked on the cell substrate, and a channel structure extending through the mold structure, and the channel structure may include an information storage circuit, a light emitting circuit, and a metal layer, sequentially stacked on side surfaces of the plurality of gate electrodes.

According to some implementations, the present disclosure is directed to a read operation, in which voltage is not applied to the unselected word, thereby reducing power consumption and the amount of heat generated by the semiconductor device, and read disturb is prevented, whereby a semiconductor device with improved reliability can be provided.

### BRIEF DESCRIPTION OF THE DRAWINGS

Example implementations will be more clearly understood from the following detailed description, taken in conjunction with the accompanying drawings.

FIG. 1 is a circuit diagram illustrating an example of a memory array region of a semiconductor device according to some implementations.

FIG. 2 is a diagram illustrating an example of a cell string including light emitting memory cells and a photodetection unit according to some implementations.

FIG. 3 is a diagram of an example of a semiconductor memory device according to some implementations.

FIG. 4 is a cross-sectional view taken along line A-A of FIG. 3 according to some implementations.

FIG. 5 is an enlarged view of an example of a region R1 of FIG. 4 according to some implementations.

FIG. 6 is a cross-sectional view taken along line B-B in FIG. 3 according to some implementations.

FIG. 7 is an enlarged view of an example of a region R2 of FIG. 5 in the semiconductor memory device including the charge trap layer according to some implementations.

FIG. 8 is a cross-sectional view illustrating an example of a portion of a memory cell region of the semiconductor memory device including the charge trap layer according to some implementations.

FIGS. 9 to 11 are diagrams showing examples of operations of the semiconductor memory device of FIG. 8 in a program mode, a read mode, and an erase mode, respectively, according to some implementations.

FIG. 12 is a cross-sectional view illustrating an example of a portion of a memory cell region of the semiconductor memory device including the charge trap layer according to some implementations.

FIG. 13 is an enlarged view showing an example of a region R2 of FIG. 5 in the semiconductor memory device including the ferroelectric layer according to some implementations.

FIG. 14 is a cross-sectional view illustrating an example of a portion of the memory cell region of the semiconductor memory device including the ferroelectric layer according to some implementations.

FIGS. 15 to 17 are diagrams showing examples of operations of the semiconductor memory device of FIG. 14 in a program mode, a read mode, and an erase mode, respectively, according to some implementations.

FIG. 18 is a diagram illustrating an example of an electronic system including a semiconductor memory device according to some implementations.

FIG. 19 is a perspective view illustrating an example of an electronic system including a 3D semiconductor memory device according to some implementations.

FIG. 20 is a cross-sectional view taken along line V-V′ of FIG. 19 according to some implementations.

### DETAILED DESCRIPTION

Hereinafter, example implementations will be explained in detail with reference to the accompanying drawings.

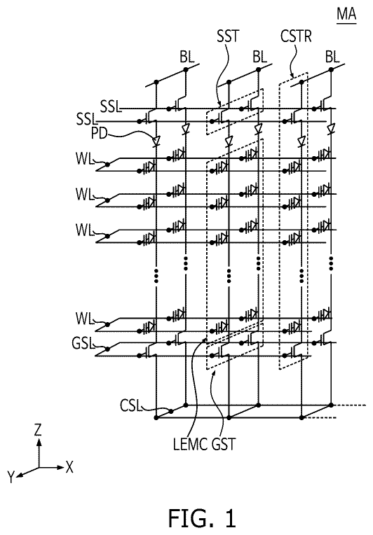

FIG. 1 is a circuit diagram illustrating an example of a memory array region MA of a semiconductor device according to some implementations. In FIG. 1, a memory array of the semiconductor device may include a common source line CSL, a plurality of bit lines BL, a plurality of cell strings CSTR disposed between the common source line CSL and the plurality of bit lines BL.

The common source line CSL may extend in a first direction X. In some implementations, a plurality of common source lines CSL may be arranged two-dimensionally.

For example, the plurality of common source lines CSL may be spaced apart from each other and may extend in the first direction X, respectively. The same voltage may be applied to the common source lines CSL, or different voltages may be applied and separately controlled.

The plurality of bit lines BL may be arranged two-dimensionally. For example, the plurality of bit lines BL may be spaced apart from each other and may extend in a second direction Y intersecting the first direction X. The plurality of cell strings CSTR may be connected to each of the bit lines BL in parallel.

The plurality of cell strings CSTR may be connected in common to the common source line CSL. Each of the plurality of cell strings CSTR may include a lower select transistor GST, light emitting memory cells LEMC, a photodetection circuit (unit) PD, and an upper select transistor SST, which may be connected to each other in series.

The light emitting memory cells LEMC may be connected in series between the lower select transistor GST, and the photodetection circuit and the string select transistor SST. Each of the light emitting memory cells LEMC may include information storage regions capable of storing information.

The photodetection circuit PD may be disposed between the upper select transistor SST and the light emitting memory cells LEMC. The photodetection circuit PD may detect the intensity of light emitted from the light emitting memory cells LEMC. For example, the photodetection circuit PD may be a P-N junction photodiode, a Schottky junction photodiode, etc.

There may be a plurality of upper select transistors SST that may be electrically connected to the bit lines BL. There may be a plurality of lower select transistors GST that may be electrically connected to the common source line CSL.

A ground select line GSL, a plurality of word lines WL, and a string select line SSL may be disposed between the common source line CSL and the bit lines BL. The upper select transistor SST may be controlled by the string select line SSL. The light emitting memory cells LEMC may be controlled by the plurality of word lines WL. For example, the string select line SSL may be used as a gate electrode of the upper select transistor SST, and a plurality of word lines WL may be used as gate electrodes of the light emitting memory cells LEMC. The lower select transistor GST may be controlled by the ground select line GSL. For example, the ground select line GSL may be used as a gate electrode of the lower select transistor GST. The common source line CSL may be connected in common to a source of the lower select transistor GST.

The string select transistor SST may be a string select transistor, and the lower select transistor GST may be a ground select transistor.

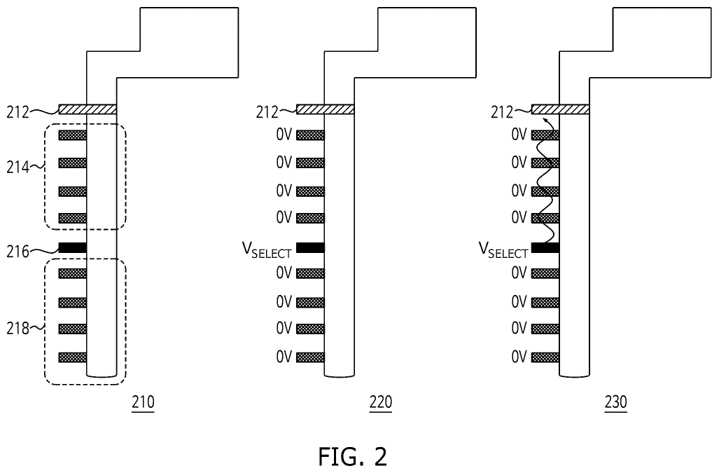

FIG. 2 is a diagram illustrating an example of a cell string including light emitting memory cells and a photodetection unit 212 according to some implementations. In FIG. 2, information may be stored in the light emitting memory cells. For example, the information storage region of the light emitting memory cells may be in various states, and information may be stored according to the state indicated by the information storage region. As a specific example, if electric charges are trapped in the information storage region of the light emitting memory cells, it may indicate a first state (e.g., off-state), and if electric charges are not trapped in the information storage region, it may indicate a second state (e.g., on-state). As another specific example, a plurality of states may be indicated according to the amount of charges trapped in the information storage region of the light emitting memory cells.

The information stored in the light emitting memory cells may be read through a read operation. As illustrated in a first example 210, a word line 216 electrically connected to a target light emitting memory cell, that is, a target of the read operation, may be selected and a predetermined voltage VSELECT may be applied to the selected word line 216 to read the information stored in the target light emitting memory cell. In the read operation, the voltage may not be applied to the unselected word lines 214 and 218.

For example, if a first predetermined voltage is applied to the selected word line 216, the intensity of light emitted from the target light emitting memory cell may vary depending on the state of the information storage region of the target light emitting memory cell. The photodetection circuit 212 may detect the intensity of the light emitted from the target light emitting memory cell, depending on which the information stored in the target light emitting memory cell may be read.

In FIG. 2, a second example 220 illustrates an example in which the read operation is performed on a target light emitting memory cell in a first state (e.g., off-state). If the target light emitting memory cell is in the first state, light may not be emitted from the target light emitting memory cell even when the predetermined voltage V_{SELECT} is applied to the selected word line 216. In this case, the photodetection circuit 212 may detect that light is not emitted from the target light emitting memory cell. Accordingly, it may be determined that the target light emitting memory cell is in the first state.

In FIG. 2, a third example 230 illustrates an example in which the read operation is performed on a target light emitting memory cell in a second state (e.g., on-state). If the target light emitting memory cell is in the second state, light may be emitted from the target light emitting memory cell when the predetermined voltage V_{SELECT} is applied to the selected word line 216. In this case, the photodetection circuit 212 may detect the light emitted from the target light emitting memory cell. Accordingly, it may be determined that the target light emitting memory cell is in the second state.

In FIG. 2, two states (e.g., on/off states) are determined according to whether the light is emitted from the light emitting memory cell. That is, it has been illustrated and described that one light emitting memory cell stores two pieces of information (e.g., binary), but the present disclosure is not limited thereto. For example, three or more states may be determined according to the intensity of light emitted from the light emitting memory cells. That is, one light emitting memory cell may store three or more pieces of information.

According to some implementations, in the read operation, the voltage may not be applied to word lines 214 and 218 that are unselected word lines. Accordingly, the power consumption and the amount of heat generated by the semiconductor device can be reduced. In addition, read disturb can be prevented, thereby improving reliability of the semiconductor device.

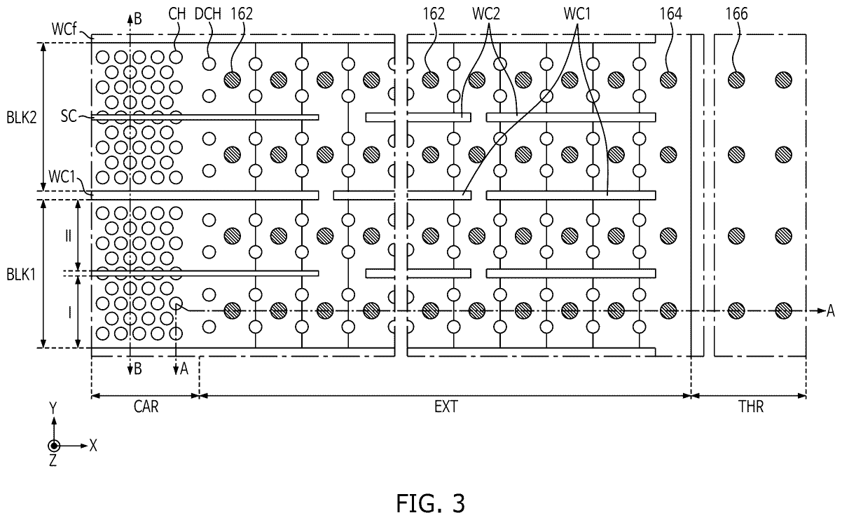

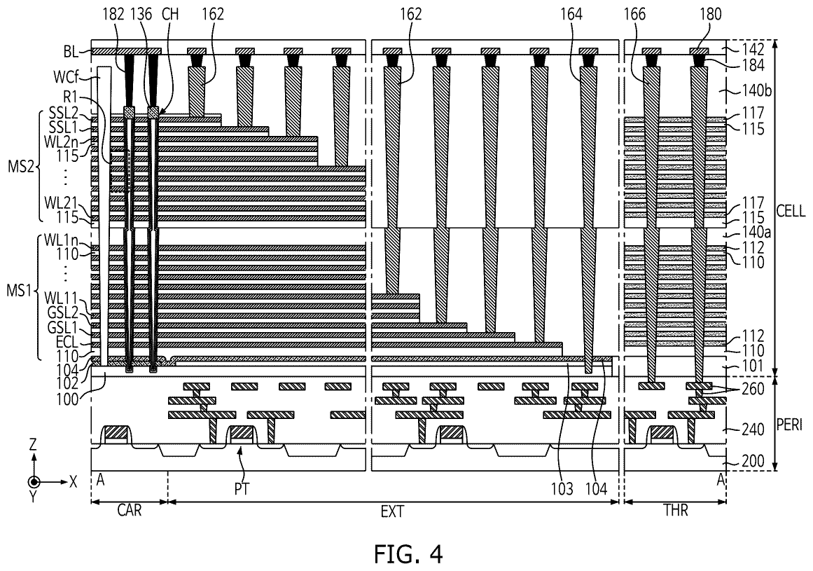

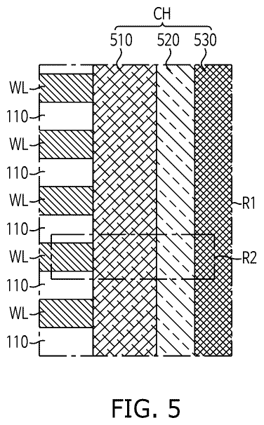

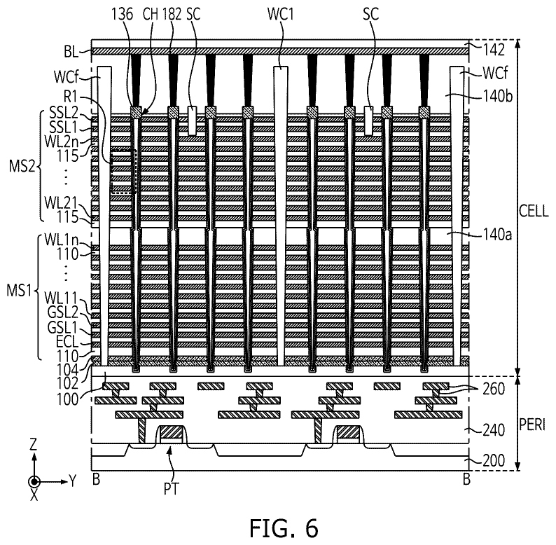

FIG. 3 is a diagram of an example of a semiconductor memory device according to some implementations. FIG. 4 is a cross-sectional view taken along line A-A of FIG. 3 according to some implementations. FIG. 5 is an enlarged of an example of a region R1 of FIG. 4 according to some implementations. FIG. 6 is a cross-sectional view taken along line B-B in FIG. 3 according to some implementations.

In FIGS. 3 to 6, the semiconductor memory device may include a memory cell region CELL and a peripheral circuit region PERI. The memory cell region CELL may include a cell substrate 100, an insulating substrate 101, mold structures MS1 and MS2, interlayer insulating films 140a and 140b, a channel structure CH, a channel pad 136, a block isolation region WCf, a bit line BL, a cell contact 162, a source contact 164, a through via 166, and a first wiring structure 180.

For example, the cell substrate 100 may include a semiconductor substrate, such as a silicon substrate, a germanium substrate, or a silicon-germanium substrate. In some implementations, the cell substrate 100 may include a silicon-on-insulator (SOI) substrate, a germanium-on-insulator (GOI) substrate, etc. In some implementations, the cell substrate 100 may include an impurity. For example, the cell substrate 100 may include a p-type impurity (e.g., boron (B), aluminum (Al), gallium (Ga), etc.). As another example, the cell substrate 100 may include an n-type impurity (e.g., phosphorus (P), arsenic (As), etc.).

The cell substrate 100 may include a cell array region CAR and an extension region EXT.

A memory cell array (e.g., MA of FIG. 1) including a plurality of memory cells (e.g., light emitting memory cells) may be formed in the cell array region CAR. For example, the channel structure CH, the bit line BL, gate electrodes ECL, GSL1, GSL2, WL11 to WL1n, WL21 to WL2n, SSL1, and SSL2, etc., as described below, may be disposed in the cell array region CAR. In the present disclosure, the surface of the cell substrate 100 on which the memory cell array is disposed may be referred to as a front side of the cell substrate 100. Additionally, the surface of the cell substrate 100 opposite to the front side of the cell substrate 100 may be referred to as a back side of the cell substrate 100.

The extension region EXT may be disposed in a peripheral region of the cell array region CAR. The gate electrodes ECL, GSL1, GSL2, WL11 to WL1n, WL21 to WL2n, SSL1, and SSL2, as described below, may be stacked in a stepwise manner in the extension region EXT.

In some implementations, the cell substrate 100 may further include a through region THR. The through region THR may be disposed inside the cell array region CAR and the extension region EXT, or may be disposed outside the cell array region CAR and the extension region EXT. The through via 166 to be described below may be disposed in the through region THR.

The insulating substrate 101 may be formed in the cell substrate 100 of the extension region EXT. The insulating substrate 101 may form an insulating region in the cell substrate 100 of the extension region EXT. For example, the insulating substrate 101 may include at least one of silicon oxide, silicon nitride, silicon oxynitride, and silicon carbide, but the present disclosure is not limited thereto. In some implementations, the insulating substrate 101 may also be formed in the cell substrate 100 of the through region THR.

In FIG. 4, a lower surface of the insulating substrate 101 is disposed coplanar with a lower surface of the cell substrate 100, but this is merely an example. As another example, the lower surface of the insulating substrate 101 may be lower than the lower surface of the cell substrate 100.

The mold structures MS1 and MS2 may be formed on the front side of the cell substrate 100. The mold structures MS1 and MS2 may include a plurality of gate electrodes ECL, GSL1, GSL2, WL11 to WL1n, WL21 to WL2n, SSL1, and SSL2 stacked on the cell substrate 100, and a plurality of mold insulating layers 110 and 115. Each of the gate electrodes ECL, GSL1, GSL2, WL11 to WL1n, WL21 to WL2n, SSL1, and SSL2 and each of the mold insulating layers 110 and 115 may have a layered structure extending parallel to the front side of the cell substrate 100. The gate electrodes ECL, GSL1, GSL2, WL11 to WL1n, WL21 to WL2n, SSL1, and SSL2 may be spaced apart from each other by the mold insulating layers 110 and 115 and sequentially stacked on the cell substrate 100.

In some implementations, the mold structures MS1 and MS2 may include a sequential stack of first mold structure MS1 and second mold structure MS2, on the cell substrate 100.

The first mold structure MS1 may include an alternating stack of first gate electrodes ECL, GSL1, GSL2, and WL11 to WL1n and first mold insulating layers 110, on the cell substrate 100. In some implementations, the first gate electrodes ECL, GSL1, GSL2, and WL11 to WL1n may include a sequential stack of erase control line ECL, ground select lines GSL1 and GSL2, and plurality of first word lines WL11 to W11n, on the cell substrate 100. The ground select lines GSL1 and GSL2 may include a sequential stack of first ground select line GSL1 and second ground select line GSL2. Although it is illustrated that the first gate electrodes ECL, GSL1, GSL2, and WL11 to WL1n include only two ground select lines GSL1 and GSL2 in some implementations, the first gate electrodes ECL, GSL1, GSL2, and WL11 to WL1n may also include three or more ground select lines or one ground select line. In some implementations, the erase control line ECL may be omitted.

The second mold structure MS2 may include an alternating stack of second gate electrodes WL21 to WL2n, SSL1, and SSL2 and second mold insulating layers 115, on the first mold structure MS1. In some implementations, the second gate electrodes WL21 to WL2n, SSL1, and SSL2 may include a sequential stack of plurality of second word lines WL21 to WL2n and string select lines SSL1 and SSL2, on the first mold structure MS1. The string select lines SSL1 and SSL2 may include a sequential stack of first string select line SSL1 and a second string select line SSL2. Although it is illustrated that the second gate electrodes WL21 to WL2n, SSL1, and SSL2 include only two string select lines SSL1 and SSL2, in some implementations the second gate electrodes WL21 to WL2n, SSL1, and SSL2 may also include three or more string select lines or one string select line.

Each of the gate electrodes ECL, GSL1, GSL2, WL11 to WL1n, WL21 to WL2n, SSL1, and SSL2 may include a conductive material, for example, a metal, such as tungsten (W), cobalt (Co), nickel (Ni), or a semiconductor material, such as silicon, but the present disclosure is not limited thereto.

Each of the mold insulating layers 110 and 115 may include an insulating material, for example, at least one of silicon oxide, silicon nitride, and silicon oxynitride, but the present disclosure is not limited thereto.

In some implementations, the mold structures MS1 and MS2 of the through region THR may include an alternating stack of plurality of mold sacrificial films 112 and 117 and plurality of mold insulating layers 110 and 115, on the cell substrate 100 and/or on the insulating substrate 101. Each of the mold sacrificial films 112 and 117 and each of the mold insulating layers 110 and 115 may have a layered structure extending parallel to an upper surface of the cell substrate 100. The mold sacrificial films 112 and 117 may be spaced apart from each other by the mold insulating layers 110 and 115 and sequentially stacked on the cell substrate 100.

In some implementations, the first mold structure MS1 of the through region THR may include an alternating stack of first mold sacrificial films 112 and first mold insulating layers 110, on the cell substrate 100, and the second mold structure MS2 of the through region THR may include an alternating stack of second mold sacrificial films 117 and second mold insulating layers 115, on the first mold structure MS1.

Each of the mold sacrificial films 112 and 117 may include an insulating material, for example, at least one of silicon oxide, silicon nitride, and silicon oxynitride, but is not limited thereto. In some implementations, the mold sacrificial films 112 and 117 may include a material having etch selectivity with respect to the mold insulating layers 110 and 115. For example, the mold insulating layers 110 and 115 may include silicon oxide, and the mold sacrificial films 112 and 117 may include silicon nitride.

The interlayer insulating films 140a and 140b may be formed on the cell substrate 100 to cover the mold structures MS1 and MS2. In some implementations, the interlayer insulating films 140a and 140b may include a sequential stack of first interlayer insulating film 140a and second interlayer insulating film 140b, on the cell substrate 100. The first interlayer insulating film 140a may cover the first mold structure MS1, and the second interlayer insulating film 140b may cover the second mold structure MS2. For example, the interlayer insulating films 140a and 140b may include at least one of silicon oxide, silicon oxynitride, and a low-k material having a dielectric constant lower than that of silicon oxide, but the present disclosure is not limited thereto.

The channel structure CH may be formed in the mold structures MS1 and MS2 of the cell array region CAR. The channel structure CH may extend through the mold structures MS1 and MS2 in a vertical direction (hereinafter, referred to as a third direction Z) intersecting the upper surface of the cell substrate 100. For example, the channel structure CH may have a pillar shape (e.g., cylindrical shape) extending in the third direction Z. Accordingly, the channel structure CH may intersect each of the gate electrodes ECL, GSL1, GSL2, WL11 to WL1n, WL21 to WL2n, SSL1, and SSL2. In some implementations, the channel structure CH may have a bent part between the first mold structure MS1 and the second mold structure MS2.

In FIG. 5, the channel structure CH may include a sequential stack of information storage circuit (unit) 510, light emitting circuit 520, and metal layer 530, on side surfaces of the mold insulating layers 110 and 115 and the gate electrodes WL. For example, a channel hole extending in the third direction Z through the mold structures MS1 and MS2 may be formed. The information storage circuit 510, the light emitting circuit 520, and the metal layer 530 may be sequentially stacked in the channel hole.

The information storage circuit 510 may be interposed between the gate electrodes WL and the light emitting unit 520. For example, an inner surface of the information storage circuit 510 may be connected to an outer surface of the light emitting circuit 520, and an outer surface of the information storage circuit 510 may be connected to the gate electrodes WL. The information storage circuit 510 may be on an outermost side of the channel structure CH. In some aspects, the information storage circuit 510 may be in the shape of a hollow cylinder (e.g., cylinder), but the present disclosure is not limited thereto.

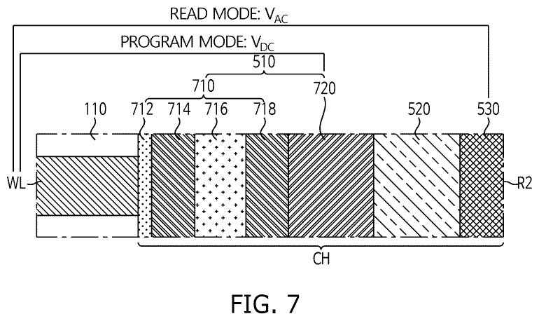

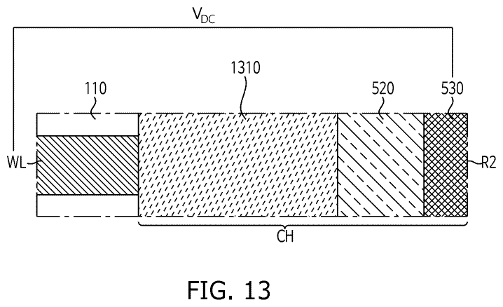

The information storage circuit 510 may store information and data. According to some implementations, the information storage circuit 510 may include a charge trap layer, which will be described in more detail below with reference to FIGS. 7 to 12. In some implementations, the information storage circuit 510 may include a ferroelectric layer, which will be described in more detail below with reference to FIGS. 13 to 17.

In FIG. 5, the light emitting circuit 520 may be interposed between the information storage circuit 510 and the metal layer 530. For example, an inner surface of the light emitting circuit 520 may be connected to an outer surface of the metal layer 530, and the outer surface of the light emitting circuit 520 may be connected to the information storage circuit 510. In some implementations, the information storage circuit 510 may be in the shape of a hollow cylinder (e.g., cylinder), but the present disclosure is not limited thereto.

The light emitting circuit 520 may include a material that emits light by recombination of electrons and holes. For example, the light emitting circuit 520 may include a light emitting diode (LED), but the present disclosure is not limited thereto. Upon application of the first predetermined voltage VSELECT to the gate electrode WL, the intensity of light emitted by the light emitting circuit 520 may vary depending on information stored in the information storage circuit 510 (e.g., amount of trapped charge, polarization state, etc.).

The metal layer 530 may fill an inner space of the light emitting circuit 520. For example, the metal layer 530 may have a pillar shape. For example, the metal layer 530 may have a cylindrical shape filling the inside of the light emitting circuit 520 having a hollow cylindrical shape. According to some implementations, the metal layer 530 may include a metal having a higher tendency to provide electrons than the gate electrodes WL.

The channel pad 136 may be disposed on the channel structure CH. The channel pad 136 may cover an upper portion of the channel structure CH. For example, the channel pad 136 may include polysilicon doped with an impurity, but the present disclosure is not limited thereto. The channel pad 136 may be in contact with a bit line contact 182 and electrically connected to the bit line contact 182.

In some implementations, the plurality of channel structures CH may be arranged in a zigzag form. For example, as illustrated in FIG. 3, the plurality of channel structures CH may be arranged to cross each other in the first direction X and the second direction Y parallel to the upper surface of the cell substrate 100. The plurality of channel structures CH arranged in the zigzag form may further improve the integration density of the semiconductor memory device. In some implementations, the plurality of channel structures CH may be arranged in a honeycomb form.

In some implementations, a dummy channel structure DCH may be formed in the mold structures MS1 and MS2 of the extension region EXT. The dummy channel structure DCH may be formed in a shape similar to that of the channel structure CH to reduce stress applied to the mold structures MS1 and MS2 in the extension region EXT.

In some implementations, first source structures 102 and 104 may be formed on the cell substrate 100. The first source structures 102 and 104 may be provided as a common source line (e.g., the CSL of FIG. 1) of the semiconductor memory device. For example, the first source structures 102 and 104 may include polysilicon or metal doped with an impurity, but the present disclosure is not limited thereto.

In some implementations, the first source structures 102 and 104 may include multiple films. For example, the first source structures 102 and 104 may include a sequential stack of first source layer 102 and second source layer 104, on the cell substrate 100. Each of the first source layer 102 and the second source layer 104 may include polysilicon doped with an impurity or polysilicon undoped with an impurity, but the present disclosure are not limited thereto. The first source layer 102 may be provided as a common source line (e.g., the CSL of FIG. 2) of the semiconductor memory device. The second source layer 104 may be used as a support layer for preventing the mold stack from collapsing or falling in a replacement process for forming the first source layer 102.

Additionally, a base insulating film may be interposed between the cell substrate 100 and the first source structures 102 and 104. For example, the base insulating film may include at least one of silicon oxide, silicon nitride, and silicon oxynitride, but the present disclosure is not limited thereto.

In some implementations, the first source structures 102 and 104 may not be formed in the extension region EXT where the insulating substrate 101 is formed. It is illustrated that the upper surface of the insulating substrate 101 is disposed coplanar with the upper surfaces of the first source structures 102 and 104, but this is merely an example. As another example, the upper surface of the insulating substrate 101 may be higher than the upper surfaces of the first source structures 102 and 104.

In some implementations, a source sacrificial film 103 may be formed on a portion of the cell substrate 100. For example, the source sacrificial film 103 may be formed on a portion of the cell substrate 100 in the extension region EXT. The source sacrificial film 103 may include a material having etch selectivity with respect to the mold insulating layers 110 and 115. For example, the mold insulating layers 110 and 115 may include silicon oxide, and the source sacrificial film 103 may include silicon nitride. The source sacrificial film 103 may be a layer remaining after a portion of the first source structures 102 and 104 is replaced with the first source layer 102 in the manufacturing process thereof.

In FIG. 6, the block isolation region WCf, a first partial isolation region WC1, and a second partial isolation region WC2 may each extend in the first direction X to cut the mold structures MS1 and MS2. The block isolation region WCf may completely cut through the mold structures MS1 and MS2. For example, the block isolation region WCf may continuously extend in the first direction X. The first partial isolation region WC1 and the second partial isolation region WC2 may each partially cut the mold structures MS1 and MS2. For example, one row of the first partial isolation regions WC1 arranged along the first direction X may be spaced apart from each other to partially cut the mold structures MS1 and MS2, and one row of the second partial isolation regions WC2 arranged along the first direction X may be spaced apart from each other to partially cut the mold structures MS1 and MS2.

The string isolation structure SC may extend in the first direction X to cut the string select lines SSL1 and SSL2. For example, the string isolation structure SC formed in a first cell block BLK1 may divide the string select lines SSL1 and SSL2 into a first zone I and a second zone II, respectively. Accordingly, the first string select line SSL1 of the first zone I and the first string select line SSL1 of the second zone II may be isolated and controlled separately, and the second string select line SSL2 of the first zone I and the second string select line SSL2 of the second zone II may be isolated and controlled separately.

The string isolation structure (SC) may include an insulating material, for example, at least one of silicon oxide, silicon nitride, and silicon oxynitride, but aspects are not limited thereto.

The bit line BL may be formed on the mold structures MS1 and MS2. The bit line BL may extend in the second direction Y and intersect the block isolation region WCf. In addition, the bit line BL may extend in the second direction Y and be connected to a plurality of channel structures CH arranged along the second direction Y. For example, the bit line contact 182 connected to an upper portion of each of the channel structures CH may be formed in the second interlayer insulating film 140b. The bit line BL may be electrically connected to the channel structures CH through the bit line contact 182.

The cell contact 162 may be connected to each of the gate electrodes ECL, GSL1, GSL2, WL11 to WL1n, WL21 to WL2n, SSL1, and SSL2. For example, the cell contact 162 may extend in the third direction Z within the interlayer insulating films 140a and 140b and connected to each of the gate electrodes ECL, GSL1, GSL2, WL11 to WL1n, WL21 to WL2n, SSL1, and SSL2. In some implementations, the cell contact 162 may include a bent part between the first mold structure MS1 and the second mold structure MS2.

The source contact 164 may be connected to the first source structures 102 and 104. For example, the source contact 164 may extend in the interlayer insulating films 140a and 140b in the third direction Z and be connected to the cell substrate 100. In some implementations, the source contact 164 may include a bent part between the first mold structure MS1 and the second mold structure MS2.

The through via 166 may be disposed in the through region THR. For example, the through via 166 may extend in the third direction Z in the mold structures MS1 and MS2 of the through region THR. In some implementations, the through via 166 may include a bent part between the first mold structure MS1 and the second mold structure MS2. Although the through via 166 extending through the mold structures MS1 and MS2 is illustrated, this is merely an example. As another example, the through via 166 may be disposed outside the mold structures MS1 and MS2 and may not extend through the mold structures MS1 and MS2.

The cell contact 162, the source contact 164, and the through via 166 may each be connected to the first wiring structure 180 on the interlayer insulating films 140a and 140b. For example, a first inter-wiring insulating film 142 may be formed on the second interlayer insulating film 140b. The first wiring structure 180 may be formed in the first inter-wiring insulating film 142. The cell contact 162, the source contact 164, and the through via 166 may each be connected to the first wiring structure 180 by a contact via 184. Additionally, the first wiring structure 180 may be connected to the bit line BL.

The peripheral circuit region PERI may include a peripheral circuit substrate 200, a peripheral circuit element PT, and a second wiring structure 260. The peripheral circuit substrate 200 may be disposed under the cell substrate 100. For example, the upper surface of the peripheral circuit substrate 200 may face the lower surface of the cell substrate 100. For example, the peripheral circuit substrate 200 may include a semiconductor substrate, such as a silicon substrate, a germanium substrate, or a silicon-germanium substrate. In some implementations, the peripheral circuit substrate 200 may also include a silicon-on-insulator (SOI) substrate, a germanium-on-insulator (GOI) substrate, etc.

The peripheral circuit element PT may be formed on the peripheral circuit substrate 200. The peripheral circuit element PT may configure a peripheral circuit that controls the operation of the semiconductor memory device. For example, the peripheral circuit element PT may include a control logic, a row decoder, a page buffer, etc. For convention, the surface of the peripheral circuit substrate 200 on which the peripheral circuit element PT is disposed may be referred to as a front side of the peripheral circuit substrate 200, and the surface of the peripheral circuit substrate 200 opposite the front side of the peripheral circuit substrate 200 may be referred to as a back side of the peripheral circuit substrate 200.

For example, the peripheral circuit element PT may include a transistor, but the present disclosure is not limited thereto. For example, the peripheral circuit element PT may include not only various active elements, such as transistors, etc., but also various passive elements, such as capacitors, resistors, inductors, etc.

In some implementations, the back side of the cell substrate 100 may face the front side of the peripheral circuit substrate 200. For example, a second inter-wiring insulating film 240 covering the peripheral circuit element PT may be formed on the front side of the peripheral circuit substrate 200. The cell substrate 100 and/or the insulating substrate 101 may be stacked on an upper surface of the second inter-wiring insulating film 240.

The first wiring structure 180 may be connected to the peripheral circuit element PT through the through via 166. For example, the second wiring structure 260 connected to the peripheral circuit element PT may be formed in the second inter-wiring insulating film 240. The through via 166 may extend in the third direction Z and connect the first wiring structure 180 and the second wiring structure 260. Accordingly, the bit line BL, each of the gate electrodes ECL, GSL1, GSL2, WL11 to WL1n, WL21 to WL2n, SSL1, and SSL2, and/or the first source structures 102 and 104 may be electrically connected to the peripheral circuit element PT.

In some implementations, the through via 166 may extend through the insulating substrate 101 and connect the first wiring structure 180 and the second wiring structure 260. As a result, the through via 166 may be electrically isolated from the cell substrate 100.

FIGS. 7 to 12 are diagrams showing an example of a semiconductor memory device including a charge trap layer 710 according to some implementations. FIG. 7 is an enlarged view of an example of a region R2 of FIG. 5 in the semiconductor memory device including the charge trap layer 710 according to some implementations. According to the present disclosure, the channel structure CH may include a sequential stack of information storage circuit 510, light emitting circuit 520, and metal layer 530, on the side surfaces of the gate electrodes WL.

In FIG. 7, the information storage circuit 510 may include a sequential stack of charge trap layer 710 and semiconductor layer 720, on the side surfaces of the gate electrodes WL. The charge trap layer 710 may be disposed between the gate electrode WL and the semiconductor layer 720. The charge trap layer may include at least one of silicon oxide, silicon nitride, silicon oxynitride, or a high-k material having a higher dielectric constant than silicon oxide. For example, the high-k material having the higher dielectric constant than silicon oxide may include at least one of aluminum oxide, hafnium oxide, lanthanum oxide, tantalum oxide, titanium oxide, lanthanum hafnium oxide, lanthanum aluminum oxide, dysprosium scandium oxide, or a combination thereof. The charge trap layer 710 may trap charges under specific conditions, and if the power of the semiconductor memory device is turned off with the charges trapped in the charge trap layer 710, the charges trapped in the charge trap layer 710 may be maintained.

In some implementations, the charge trap layer 710 may include multiple films. For example, the charge trap layer 710 may include a sequential stack of first oxide layer 714, nitride layer 716, and second oxide layer 718, on the side surfaces of the gate electrode WL. For example, the first oxide layer 714 may include silicon oxide or a high-k material (e.g., aluminum oxide (Al₂O₃), hafnium oxide (HfO₂), etc.) having a higher dielectric constant than silicon oxide, but the present disclosure is not limited thereto. In some implementations, the first oxide layer 714 may be referred to as a blocking insulating layer.

For example, the nitride layer 716 may include silicon nitride (SiNx), but the present disclosure is not limited thereto. In some implementations, the nitride layer 716 may be referred to as a charge storage layer.

For example, the second oxide layer 718 may include silicon oxide or a high-k material having a higher dielectric constant than silicon oxide, but is not limited thereto. In some implementations, the second oxide layer 718 may be referred to as a tunnel insulating layer.

According to some implementations, the charge trap layer 710 may further include an aluminum oxide layer 712 disposed between the gate electrode WL and the first oxide layer 714. The aluminum oxide layer 712 may include a high-k material having a higher dielectric constant than that of the first oxide layer 714. For example, if the first oxide layer 714 includes silicon oxide, the aluminum oxide layer 712 may include aluminum oxide (Al₂O₃), etc.

The semiconductor layer 720 may be disposed between the charge trap layer 710 and the light emitting circuit 520. For example, the semiconductor layer 720 may include a semiconductor material, such as single crystal silicon, polycrystalline silicon, an organic semiconductor material, or a carbon nanostructure, but the present disclosure is not limited thereto. In some implementations, the semiconductor layer 720 may include an impurity. For example, the semiconductor layer 720 may include a p-type impurity (e.g., boron (B), aluminum (Al), gallium (Ga), etc.). As another example, the semiconductor layer 720 may include an n-type impurity (e.g., phosphorus (P), arsenic (As), etc.).

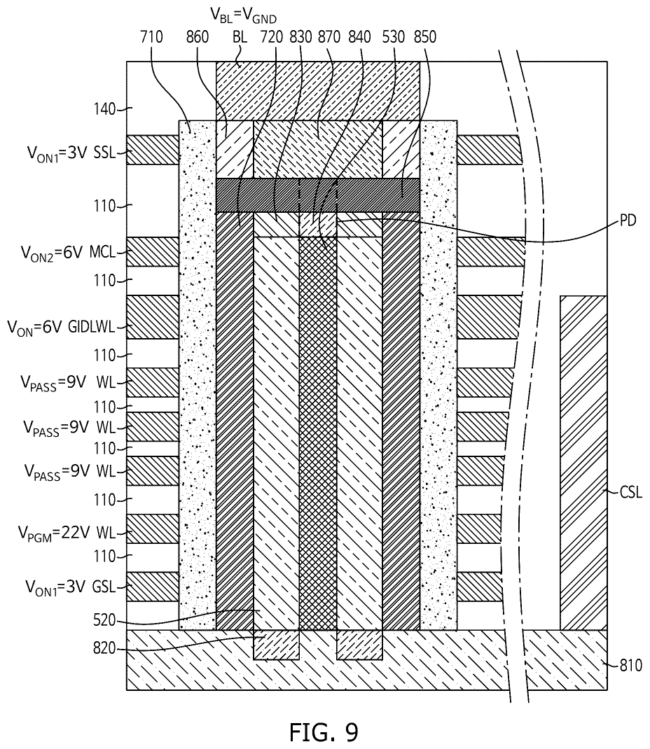

In a first mode (e.g., a program mode), a voltage VDC (e.g., a direct current voltage) may be applied between the gate electrode WL and the semiconductor layer 720. For example, a relatively high DC voltage may be applied to the gate electrode WL, and as a result, electric charges may be trapped in the charge trap layer 710. In the first mode, the same voltage as that applied to the semiconductor layer 720 may be applied to the metal layer 530, and accordingly, current may not flow between the semiconductor layer 720 and the metal layer 530. That is, an electric field due to the voltage V_{DC} may be formed between the gate electrode WL and the semiconductor layer 720. The operation of the semiconductor memory device in the first mode will be described below in more detail with reference to FIG. 9.

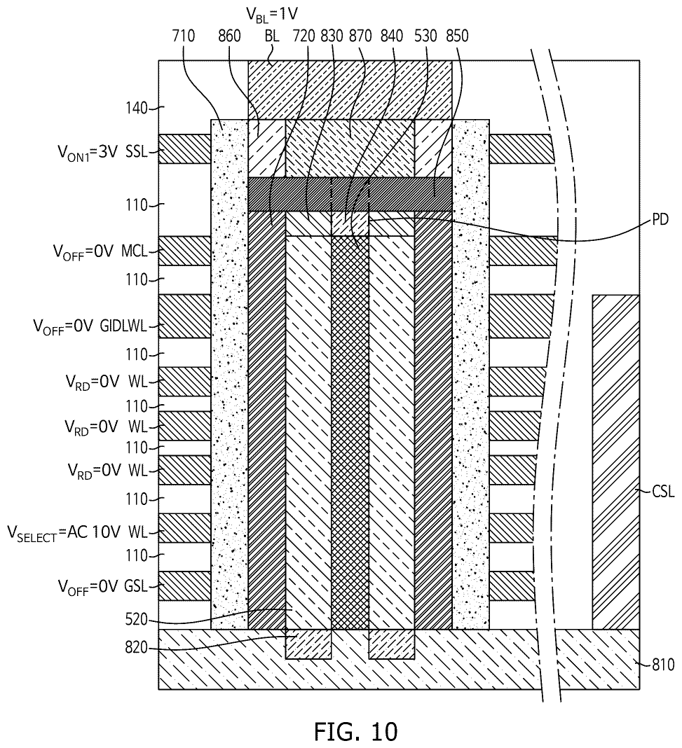

In a second mode (e.g., a read mode), a voltage V_{AC} (e.g., an AC voltage) for driving the light emitting circuit 520 may be applied between the gate electrode WL and the metal layer 530. That is, an electric field due to the voltage V_{AC} may be formed between the gate electrode WL and the metal layer 530. Accordingly, light may be emitted by recombination of electrons and holes in the light emitting circuit 520. In this case, the intensity of light emitted from the light emitting circuit 520 may vary according to the amount of electric charges trapped in the charge trap layer 710. The operation of the semiconductor memory device in the second mode will be described below in more detail with reference to FIG. 10.

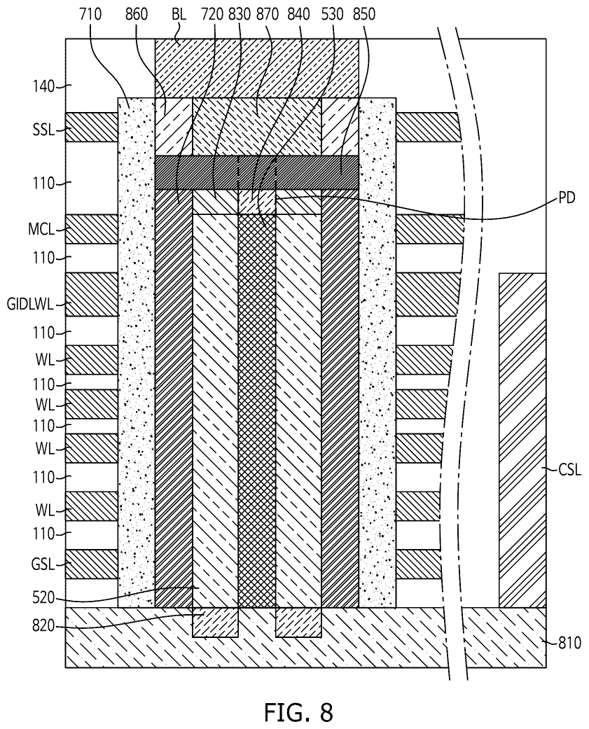

FIG. 8 is a cross-sectional view illustrating an example of a portion of a memory cell region of the semiconductor memory device including the charge trap layer 710 according to some implementations. In FIG. 8, the semiconductor memory device may include a cell substrate 810, a mold structure including an alternating stack of plurality of gate electrodes GSL, WL, and SSL and plurality of mold insulating layers 110, on the cell substrate 810, and a channel structure extending through the mold structure.

The plurality of gate electrodes may include a plurality of word line electrodes WL. In addition, the plurality of gate electrodes may include, disposed on the plurality of word line electrodes WL, a GIDL electrode GIDLWL, a mode control line gate electrode MCL, and a string select line gate electrode SSL, and a ground select line gate electrode GSL disposed under the plurality of word line electrodes WL. For example, the GIDL electrode GIDLWL, the mode control line gate electrode MCL, and the string select line gate electrode SSL may be sequentially stacked on the plurality of gate electrodes WL. A voltage may be applied to the GIDL electrode (GIDL electrode) and the mode control line gate electrode MCL only in a certain mode (e.g., a program mode).

The channel structure extending through the mold structure may include a sequential stack of charge trap layer 710, semiconductor layer 720, light emitting circuit 520, and metal layer 530, on the side surfaces of the plurality of gate electrodes. The channel structure may further include photodetection circuits 830, 840, and 850. The photodetection circuits 830, 840, and 850 may be disposed on the metal layer 530, the light emitting circuit 520, and the semiconductor layer 720. According to some implementations, the photodetection circuits 830, 840, and 850 may include a first insulating layer 830 disposed on the light emitting circuit 520, an n-type semiconductor layer 840 disposed on the metal layer 530, and a p-type semiconductor layer 850 disposed on the semiconductor layer 720, the first insulating layer 830, and the n-type semiconductor layer 840. The n-type semiconductor layer 840 may include a semiconductor material (e.g., silicon, germanium, etc.) and an n-type impurity (e.g., phosphorus (P), arsenic (As), etc.). The p-type semiconductor layer 850 may include a semiconductor material (e.g., silicon, germanium, etc.) and a p-type impurity (e.g., boron (B), aluminum (Al), gallium (Ga), etc.).

At least some region of the n-type semiconductor layer 840 and the p-type semiconductor layer 850 may serve as a photodiode PD. The photodiode PD may detect the intensity of light emitted from the light emitting circuit 520. For example, the magnitude of the current flowing through the photodiode PD may vary according to the intensity of light emitted from the light emitting circuit 520. The photodiode PD may be a P-N junction photodiode.

The channel structure may further include an additional semiconductor layer 860 and a second insulating layer 870, which are disposed on the photodetection circuits 830, 840, and 850 and stacked sequentially on the side surface of the charge trap layer 710. In addition, a bit line BL (or a bit line contact electrically connected to the bit line BL) may be disposed on the channel structure. The bit line BL may be electrically connected to the additional semiconductor layer 860. In addition, the bit line BL may be electrically insulated from the charge trap layer 710.

In FIG. 8, a third insulating layer 820 may be disposed between the light emitting circuit 520 and the cell substrate 810.

According to some implementations, the string select line gate electrode SSL may be positioned between the photodetection circuits 830, 840, and 850 and the bit line BL. For example, the string select line gate electrode SSL may be positioned above the uppermost portion of the photodetection circuits 830, 840, and 850 and below the lowermost portion of the bit line BL. In addition, the mode control line gate electrode MCL may be positioned below the lowermost portion of the photodetection circuits 830, 840, and 850 and above the plurality of word line electrodes WL.

FIGS. 9 to 11 are diagrams an examples of operations of the semiconductor memory device of FIG. 8 in a program mode, a read mode, and an erase mode, respectively, according to some implementations. The specific voltage values applied to each electrode are illustrated in FIGS. 9 to 11 and will be described below, but these values are merely examples for describing a relative magnitude of the voltage values applied to each electrode, and the present disclosure is not limited thereto.

In FIG. 9, in the program mode, a ground voltage V_{GND} may be applied to a program target bit line BL, which is a bit line electrically connected to the program target light emitting memory cells. An operating voltage V_{DD} may be applied to an inhibited bit line, which is a bit line not electrically connected to the program target light emitting memory cells.

A first predetermined voltage V_{PGM} (for example, 22V) may be applied to at least some of the word line gate electrodes (hereinafter, referred to as program target gate electrodes) associated with the program target light emitting memory cells. In this case, the voltage applied to the program target gate electrode may be a DC voltage. In addition, a second predetermined voltage V_{PASS} (e.g., 9V) lower than the first predetermined voltage may be applied to the word line gate electrodes other than the program target gate electrode.

A third predetermined voltage V_{ON1} (e.g., 3V) may be applied to the string select line gate electrode SSL and the ground select line gate electrode GSL. In addition, a fourth predetermined voltage V_{ON2} (e.g., 6V) may be applied to the mode control line gate electrode MCL and the GIDL electrode GIDLWL. The mode control line gate electrode MCL and the GIDL electrode GIDLWL may be applied only in the program mode.

As a result, electric charges may be trapped in the program target light emitting memory cells. That is, the electric charges may be trapped in a region of the charge trap layer 710 which is associated with the program target gate electrode.

In FIG. 10, in the read mode, a fifth predetermined voltage V_{SELECT} (e.g., AC 10V) for driving the light emitting circuit 520 may be applied to the selected gate electrode which is a word line gate electrode associated with read target light emitting memory cells. In this case, the fifth predetermined voltage applied to the selected gate electrode may be an AC voltage. However, this is only an example, and the fifth predetermined voltage applied to the selected gate electrode may be a DC voltage. In addition, a voltage may not be applied to the word line gate electrodes other than the selected gate electrode (V_{RD}=0V).

The third predetermined voltage V_{ON1} (e.g., 3V), may be applied to the string select line gate electrode SSL. In addition, a voltage may not be applied to the ground select line gate electrode GSL, the mode control line gate electrode MCL, and the GIDL electrode GIDLWL (V_{OFF}=0V).

A sixth predetermined voltage (e.g., 1V) may be applied to a read target bit line BL, which is a bit line electrically connected to the read target light emitting memory cells.

The intensity of light emitted from the light emitting circuit 520 may vary according to the amount of charge trapped in some region of the charge trap layer 710 associated with the read target light emitting memory cell. The photodiode PD may detect the intensity of light emitted from the light emitting circuit 520.

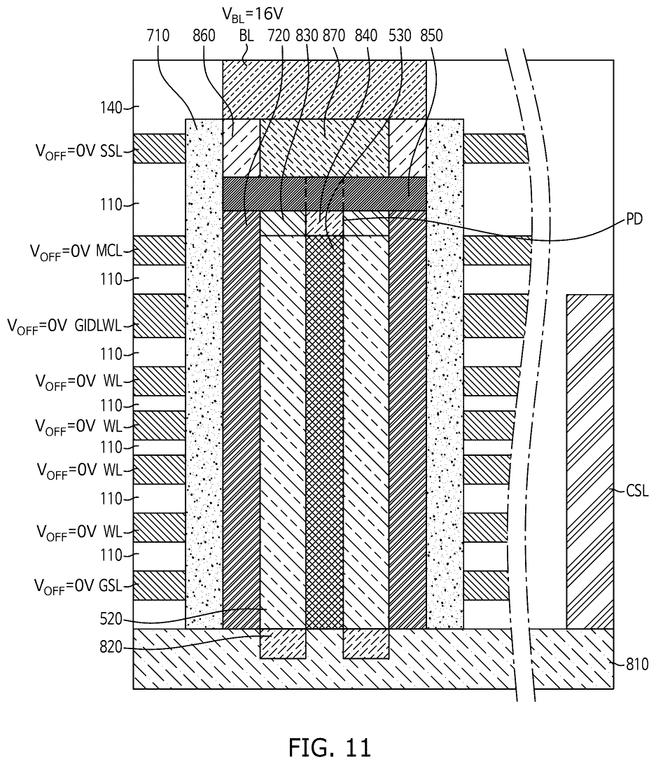

In FIG. 11, in the erase mode, a seventh predetermined voltage (e.g., 16V) may be applied to an erase target bit line, and a voltage may not be applied to the plurality of gate electrodes (V_{OFF}=0V). As a result, electric charges trapped in the charge trap layer 710 may exit to the semiconductor layer 720.

As described above, using the mode control line gate electrode MCL, the electrode across which voltage is applied may be set differently in each mode (program mode, read mode, erase mode, etc.). For example, the voltage applied to the mode control line gate electrode MCL in each mode may be controlled differently (e.g., V_{ON2} in program mode, V_{OFF} in read mode), so the electrode across which voltage is applied may be set differently. Accordingly, the region where the electric field is applied may vary in each mode (e.g., region between the program target gate electrode and the semiconductor layer 720 in the program mode, region between the read target gate electrode and the metal layer 530 in the read mode).

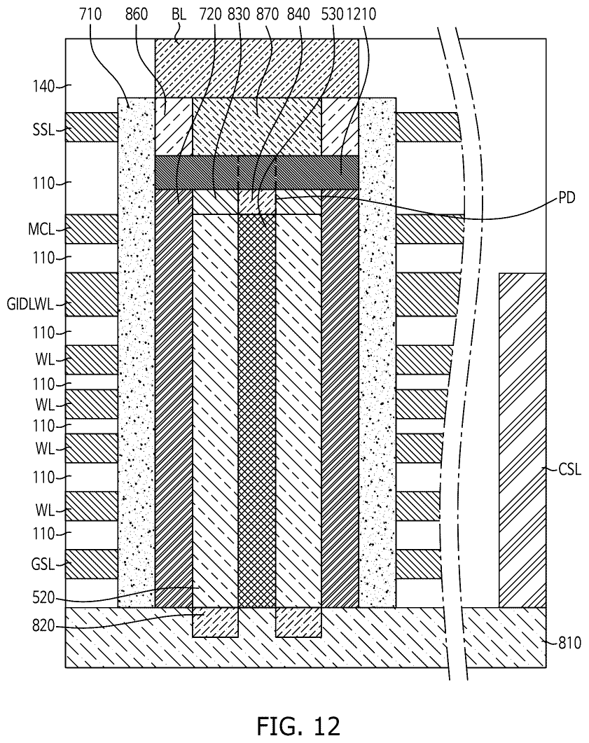

FIG. 12 is a cross-sectional view illustrating an example of a portion of a memory cell region of the semiconductor memory device including the charge trap layer 710 according to some implementations. According to some implementations, the photodetection circuits 830, 840, and 850 may include the insulating layer 830 disposed on the light emitting circuit, the n-type semiconductor layer 840 disposed on the metal layer 530, and an additional metal layer 1210 disposed on the n-type semiconductor layer 720, the semiconductor layer 840, and the insulating layer 830. At least some region of the n-type semiconductor layer 840 and the additional metal layer 1210 may serve as a photodiode PD. The photodiode PD may be a Schottky junction photodiode.

FIGS. 13 to 17 are diagrams showing examples of a semiconductor memory device including a ferroelectric layer 1310 according to some implementations. FIG. 13 is an enlarged view showing an example of a region R2 of FIG. 5 in the semiconductor memory device including the ferroelectric layer 1310 according to some implementations. According to the present disclosure, the channel structure CH may include a sequential stack of ferroelectric layer 1310, light emitting circuit 520, and metal layer 530, on the side surfaces of the gate electrodes WL. If the electric field is applied to the ferroelectric layer 1310, polarization state may be maintained, and the polarization state may be maintained even if the power of the semiconductor memory device is turned off. That is, the ferroelectric layer 1310 may serve as an information storage circuit.

The ferroelectric layer 1310 may include a ferroelectric material. For example, the ferroelectric layer 1310 may include a hafnium-based compound having ferroelectric properties. For example, the ferroelectric layer 1310 may include HfO₂, HfZnO, HfSiO, HfSiON, HfTaO, HfTiO, HfZrO, or a combination thereof, but the present disclosure is not limited thereto. For example, the ferroelectric layer 1310 may include a ferroelectric material having a perovskite structure such as PZT(PbZrxTi1-xO₃), BaTiO₃, PbTiO₃, etc. The ferroelectric layer 1310 may include at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La). The ferroelectric layer 1310 may be formed of a crystalline material. For example, the ferroelectric layer 1310 may have a crystal structure of an orthorhombic system.

In FIG. 13, with respect to the ferroelectric layer 1310, a direct current voltage VDC may be applied between the gate electrode WL and the metal layer 530 in all of the program mode, read mode, and erase mode.

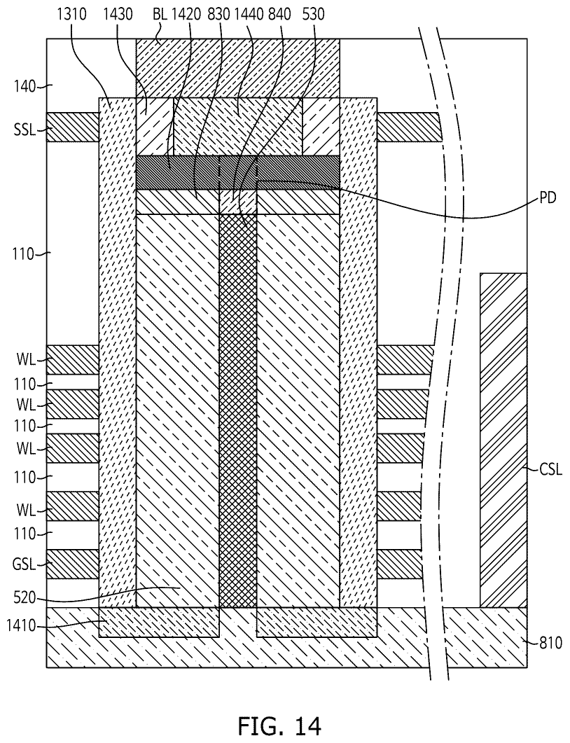

FIG. 14 is a cross-sectional view illustrating an example of a portion of the memory cell region of the semiconductor memory device including the ferroelectric layer 1310 according to some implementations. In FIG. 14, the semiconductor memory device may include the cell substrate 810, the mold structure including the alternating stack of plurality of gate electrodes GSL, WL, and SSL and plurality of mold insulating layers 110, on the cell substrate 810, and the channel structure extending through the mold structure.

The plurality of gate electrodes may include the plurality of word line electrodes WL. In addition, the plurality of gate electrodes may include the string select line gate electrode SSL arranged above the plurality of word line electrodes WL, and the ground select line gate electrode GSL disposed under the plurality of word line electrodes WL. That is, the GIDL electrode (GIDLWL of FIG. 8) and the mode control line gate electrode (MCL of FIG. 8) may be omitted in the semiconductor memory device including the ferroelectric layer 1310.

The channel structure extending through the mold structure may include a sequential stack of ferroelectric layer 1310, light emitting circuit 520, metal layer 530, and photodetection circuits 830, 840, and 1420 disposed on the metal layer 530, on the side surfaces of the plurality of gate electrodes. The photodetection circuits 830, 840, and 1420 may include the first insulating layer 830 disposed on the light emitting circuit 520, the n-type semiconductor layer 840 disposed on the metal layer 530, and a p-type semiconductor layer 1420 disposed on the n-type semiconductor layer 840 and the first insulating layer 830.

The channel structure may further include an additional semiconductor layer 1430 and a second insulating layer 1440 which are disposed on the photodetection circuits 830, 840, and 1420 and stacked sequentially on the side surface of the ferroelectric layer 1310. In addition, a bit line BL electrically connected to the additional semiconductor layer 1430 may be disposed on the channel structure, and the bit line BL may be electrically insulated from the ferroelectric layer 1310.

In FIG. 14, a third insulating layer 1410 may be disposed between the ferroelectric layer 1310, the light emitting circuit 520, and the cell substrate 810.

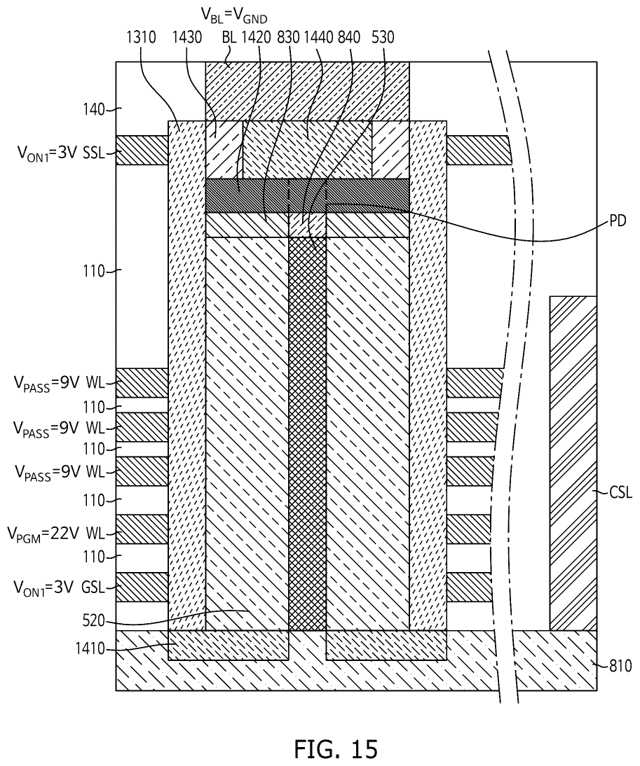

FIGS. 15 to 17 are diagrams showing examples of operations of the semiconductor memory device of FIG. 14 in a program mode, a read mode, and an erase mode, respectively, according to some implementations. The specific voltage values applied to each electrode are illustrated in FIGS. 15 to 17 and will be described below, but these values are merely examples for describing a relative magnitude of the voltage values applied to each electrode, and the present disclosure is not limited thereto.

In FIG. 15, in the program mode, a ground voltage V_{GND} may be applied to a program target bit line BL, which is a bit line electrically connected to the program target light emitting memory cells. An operating voltage V_{DD} may be applied to an inhibited bit line, which is a bit line not electrically connected to the program target light emitting memory cells.

A first predetermined voltage V_{PGM} (for example, 22V) may be applied to at least some of the word line gate electrodes (hereinafter, referred to as program target gate electrodes) associated with the program target light emitting memory cells. In this case, the voltage applied to the program target gate electrode may be a DC voltage. In addition, a second predetermined voltage V_{PASS} (e.g., 9V) lower than the first predetermined voltage may be applied to the word line gate electrodes other than the program target gate electrode.

In FIG. 14, a third predetermined voltage V_{ON1} (e.g., 3V) may be applied to the string select line gate electrode SSL and the ground select line gate electrode GSL.

Accordingly, the polarity of at least some region of the ferroelectric layer 1310 associated with the program target light emitting memory cells may change. That is, at least some region of the ferroelectric layer 1310 associated with the program target light emitting memory cells may be in a polarization state. The changed polarity (polarization state) may be maintained even after the external electric field is removed.

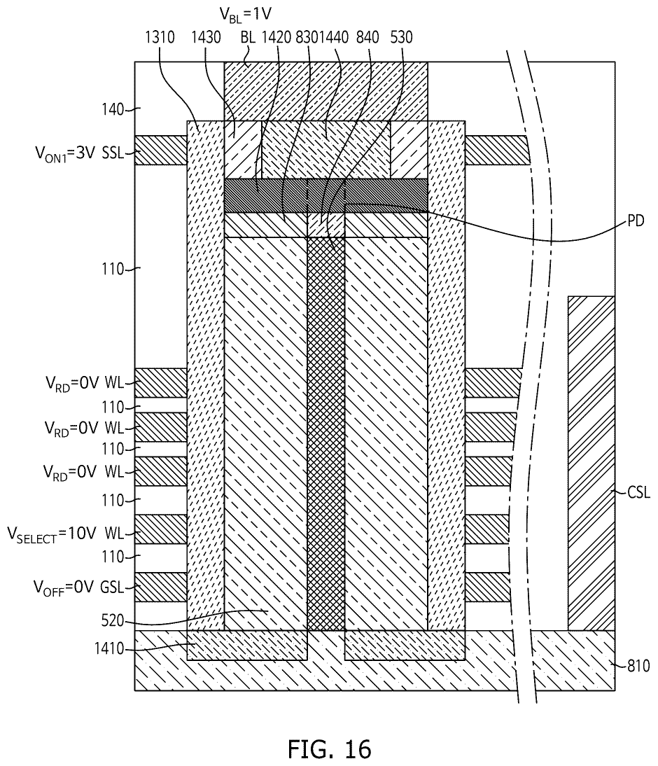

In FIG. 16, in the read mode, a fourth predetermined voltage V_{SELECT} (e.g., DC 10V) may be applied to a selected gate electrode, which is a word line gate electrode associated with the read target light emitting memory cells. In this case, the voltage applied to the selected gate electrode may be a DC voltage. In addition, a voltage may not be applied to the word line gate electrodes other than the selected gate electrode (V_{RD}=0V).

A fifth predetermined voltage V_{ON1} (e.g., 3V), may be applied to the string select line gate electrode SSL. In addition, a voltage may not be applied to the ground select line gate electrode GSL (V_{OFF}=0V).

A sixth predetermined voltage (e.g., 1V) may be applied to a read target bit line BL, which is a bit line electrically connected to the read target light emitting memory cells.

The intensity of light emitted from the light emitting circuit 520 may vary according to the degree of polarization of at least some region of the ferroelectric layer 1310 associated with the read target light emitting memory cells. The photodiode PD may detect the intensity of light emitted from the light emitting circuit 520.

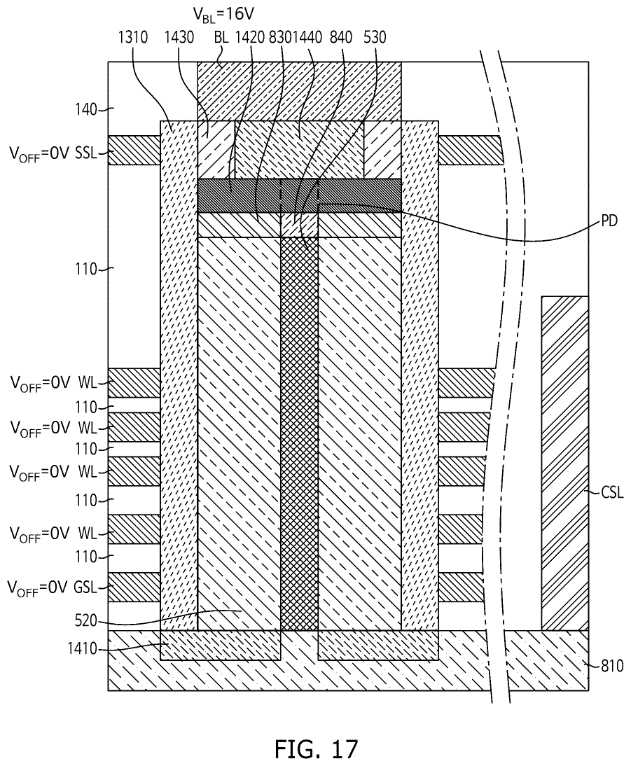

In FIG. 17, in the erase mode, a seventh predetermined voltage (e.g., 16V) may be applied to an erase target bit line, and a voltage may not be applied to the plurality of gate electrodes (V_{OFF}=0V). Accordingly, the changed polarity of the ferroelectric layer 1310 may be returned to its original state.

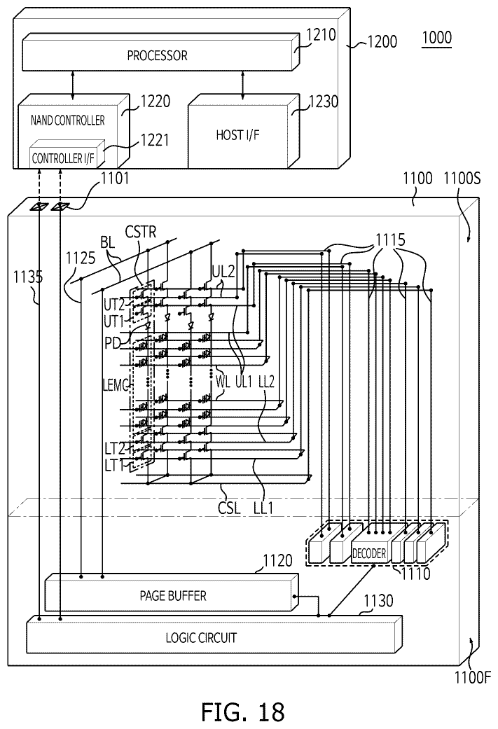

FIG. 18 is a diagram illustrating an example of an electronic system 1000 including a semiconductor memory device 1100 according to some implementations. In FIG. 18, the electronic system 1000 may include a 3D semiconductor memory device 1100 and a controller 1200 electrically connected to the 3D semiconductor memory device 1100. The electronic system 1000 may be a storage device including one or a plurality of 3D semiconductor memory devices 1100 or an electronic device including a storage device. For example, the electronic system 1000 may be a solid state drive device (SSD), a universal serial bus (USB), a computing system, a medical device, or a communication device including one or a plurality of semiconductor memory devices 1100.

The 3D semiconductor memory device 1100 may be a non-volatile memory device, and may be a 3D NAND flash memory device as described below, for example. The 3D semiconductor memory device 1100 may include a first region 1100F and a second region 1100S on the first region 1100F. For example, the first region 1100F may be disposed next to the second region 1100S. In addition, the first region 1100F may be a peripheral circuit region including a decoder circuit 1110, a page buffer 1120, and a logic circuit 1130. The second region 1100S may be a memory cell region including a bit line BL, a common source line CSL, word lines WL, first lines LL1 and LL2, second lines UL1 and UL2, and memory cell strings CSTR between the bit line BL and the common source line CSL.

In the second region 1100S, each of the memory cell strings CSTR may include first transistors LT1 and LT2 adjacent to the common source line CSL, second transistors UT1 and UT2 adjacent to the bit line BL, a photodiode PD disposed between the first transistors LT1 and LT2 and the second transistors UT1 and UT2, and a plurality of light emitting memory cells LEMC. The number of the first transistors LT1 and LT2 and the number of the second transistors UT1 and UT2 may be variously modified according to aspects.

For example, the first transistors LT1 and LT2 may include a ground select transistor, and the second transistors UT1 and UT2 may include a string select transistor and a mode control transistor. The first lines LL1 and LL2 may be gate electrodes of the first transistors LT1 and LT2, respectively. The word lines WL may be gate electrodes of the light emitting memory cells LEMC. The second lines UL1 and UL2 may be gate electrodes of the second transistors UT1 and UT2, respectively.

For example, the first transistors LT1 and LT2 may include a first erase control transistor LT1 and a ground select transistor LT2 connected to each other in series. The second transistors UT1 and UT2 may include a string select transistor UT1 and a second erase control transistor UT2 connected to each other in series. At least one of the first erase control transistor LT1 and the second erase control transistor UT2 may be used for an erase operation of erasing data stored in the light emitting memory cells LEMC using a gate induced leakage current (GIDL) phenomenon.

The common source line CSL, the first lines LL1 and LL2, the word lines WL, and the second lines UL1 and UL2 may be electrically connected to the decoder circuit 1110 through first connection lines 1115 extending from the first region 1100F to the second region 1100S. The bit line BL may be electrically connected to the page buffer 1120 through a second connection wiring 1125 extending from within the first region 1100F and to the second region 1100S.

In the first region 1100F, the decoder circuit 1110 and the page buffer 1120 may perform a control operation on at least one light emitting memory cell selected from among the plurality of light emitting memory cells LEMC. The decoder circuit 1110 and the page buffer 1120 may be controlled by the logic circuit 1130. The 3D semiconductor memory device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first region 1100F and to the second region 1100S.

The controller 1200 may include a processor 1210, a NAND controller 1220, and a host interface 1230. For example, the electronic system 1000 may include a plurality of 3D semiconductor memory devices 1100, and in this case, the controller 1200 may control the plurality of 3D semiconductor memory devices 1100.

The processor 1210 may control the overall operation of the electronic system 1000 including the controller 1200. The processor 1210 may operate according to predetermined firmware, and may control the NAND controller 1220 to access the 3D semiconductor memory device 1100. The NAND controller 1220 may include a NAND controller interface 1221 that processes communication with the 3D semiconductor memory device 1100. A control command for controlling the 3D semiconductor memory device 1100, data to be written to the light emitting memory cells LEMC of the 3D semiconductor memory device 1100, data to be read from the light emitting memory cells LEMC of the 3D semiconductor memory device 1100, etc. may be transmitted through the NAND controller interface 1221. The host interface 1230 may provide a function of communication between the electronic system 1000 and an external host. Upon receiving a control command from the external host through the host interface 1230, the processor 1210 may control the 3D semiconductor memory device 1100 in response to the control command.

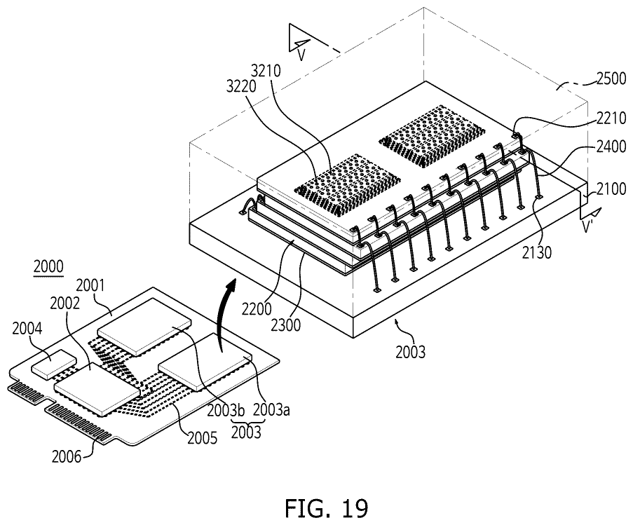

FIG. 19 is a perspective view illustrating an example of an electronic system 2000 including a 3D semiconductor memory device according to some implementations. In FIG. 19, the electronic system 2000 may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 provided to the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. For example, the electronic system 2000 may communicate with the external host according to any one of interfaces, such as Universal Serial Bus (USB), Peripheral Component Interconnect Express (PCI-Express), Serial Advanced Technology Attachment (SATA), M-Phy for Universal Flash Storage (UFS), Compute Express Link (CXL), Universal Chiplet Interconnect Express (UCIe), etc. For example, the electronic system 2000 may operate by the power supplied from the external host through the connector 2006. The electronic system 2000 may further include a Power Management Integrated Circuit (PMIC) that distributes the power supplied from the external host to the controller 2002 and the semiconductor package 2003.

In FIG. 19, the controller 2002 may record data in the semiconductor package 2003 or read data from the semiconductor package 2003, and may improve the operation speed of the electronic system 2000.

The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit substrate including package upper pads 2130. Each of the semiconductor chips 2200 may include input and output pads 2210. Each of the semiconductor chips 2200 may include gate stack structures 3210 and vertical channel structures 3220. Each of the semiconductor chips 2200 may include the 3D semiconductor memory device described above.

For example, the connection structure 2400 may be a bonding wire electrically connecting the input and output pads 2210 and the package upper pads 2130. In each of the first and second semiconductor packages 2003a and 2003b, the semiconductor chips 2200 may be electrically connected to each other with the bonding wire method, and may be electrically connected to the package upper pads 2130 of the package substrate 2100. According to some implementations, in each of the first and second semiconductor packages 2003a and 2003b, the semiconductor chips 2200 may be electrically connected to each other by through-electrodes (Through Silicon Via, TSV), instead of the bonding wire type connection structure 2400.

For example, the controller 2002 and the semiconductor chips 2200 may be included in one package. For example, the controller 2002 and the semiconductor chips 2200 may be mounted on a separate interposer substrate different from the main substrate 2001, and the controller 2002 and the semiconductor chips 2200 may be connected to each other by wiring provided on the interposer substrate.

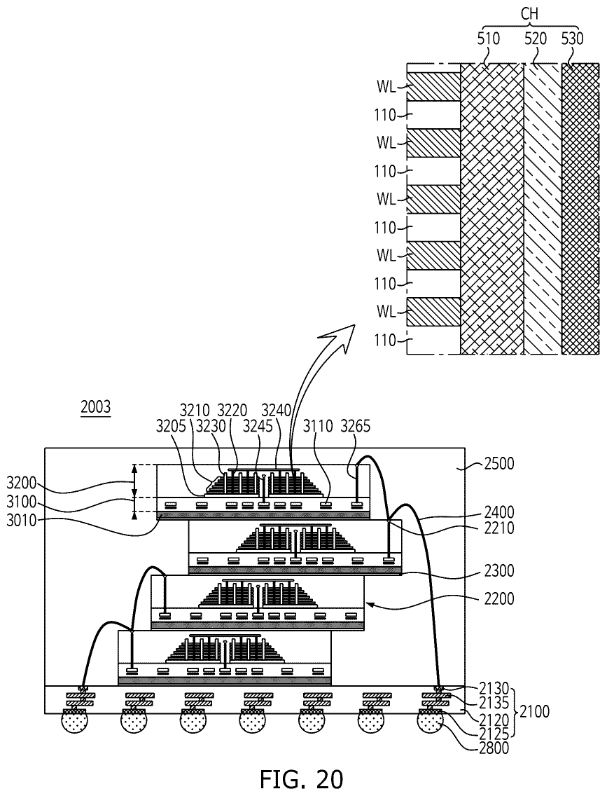

FIG. 20 is a cross-sectional view taken along line V-V′ of FIG. 19 according to some implementations. In FIG. 20, the semiconductor package 2003 may include the package substrate 2100, the plurality of semiconductor chips 2200 on the package substrate 2100, and the molding layer 2500 covering the package substrate 2100 and the plurality of semiconductor chips.

The package substrate 2100 may include a package substrate body portion 2120, the package upper pads 2130 disposed on the upper side of the package substrate body portion 2120, lower pads 2125 disposed on the lower side of the package substrate body portion 2120 or exposed through the lower side, and internal wirings 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of a main substrate 2010 of the electronic system 2000 illustrated in FIG. 19 through conductive connection portions 2800.

Each of the semiconductor chips 2200 may include a semiconductor substrate 3010, and a sequential stack of first structure 3100 and second structure 3200, on the semiconductor substrate 3010. The first structure 3100 may include a peripheral circuit region including peripheral wirings 3110. The second structure 3200 may include a common source line 3205, a gate stack structure 3210 on the common source line 3205, the vertical channel structures 3220 and isolation structures 3230 extending through the gate stack structure 3210, bit lines 3240 electrically connected to the vertical channel structures 3220, and gate connection wirings and conductive lines electrically connected to the word lines (WL of FIG. 18) of the gate stack structure 3210. Each of the semiconductor chips 2200 may include a through wiring 3245 electrically connected to the peripheral wirings 3110 of the first structure 3100 and extending into the second structure 3200. The through wiring 3245 may extend through the gate stack structure 3210 and may be further disposed outside the gate stack structure 3210. Each of the semiconductor chips 2200 may further include an input and output connection wiring 3265 electrically connected to the peripheral wirings 3110 of the first structure 3100 and extending into the second structure 3200, and the input and output pad 2210 electrically connected to the input and output connection wiring 3265.

In some implementations, each of the semiconductor chips 2200 may include the semiconductor memory device described above with reference to FIGS. 1 to 18. For example, the second structure 3200 of the semiconductor chips 2200 may include the cell substrate 100, the plurality of mold structures MS1 and MS2 each including the alternating stack of plurality of gate electrodes WL and plurality of mold insulating layers 110, on the cell substrate 100, and the channel structure CH extending through the mold structure, which are described above with reference to FIGS. 3 to 6. In addition, the channel structure CH may include the information storage device 510, the light emitting circuit 520, and the metal layer 530 which are described above with reference to FIG. 5.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device, comprising:
a substrate;
a mold structure including a plurality of gate electrodes and a plurality of mold insulating layers, alternatively stacked on the substrate; and
a channel structure extending into the mold structure,
wherein the channel structure includes an information storage circuit, a light emitting circuit, and a first metal layer, sequentially stacked on side surfaces of the plurality of gate electrodes,
wherein the channel structure further includes a photodetection circuit disposed on the first metal layer,
wherein the photodetection circuit is configured to detect light emitted from the light emitting circuit, and
wherein a level of light detected by the photodetection circuit is indicative of a memory state of the information storage circuit.

2. The semiconductor memory device according to claim 1,
wherein the photodetection circuit includes a first semiconductor layer disposed on the first metal layer, an insulating layer disposed on the light emitting circuit, and a second semiconductor layer disposed on the first semiconductor layer and the insulating layer,
wherein the first semiconductor layer includes an n-type layer, and
wherein the second semiconductor layer includes a p-type layer.

3. The semiconductor memory device according to claim 1,
wherein the photodetection circuit includes a first semiconductor layer disposed on the first metal layer, an insulating layer disposed on the light emitting circuit, and a second metal layer disposed on the first semiconductor layer and the insulating layer, and wherein the first semiconductor layer includes an n-type layer.

4. The semiconductor memory device according to claim 1, wherein the information storage circuit includes a charge trap layer and a first semiconductor layer, sequentially stacked on the side surfaces of the plurality of gate electrodes.

5. The semiconductor memory device according to claim 4, wherein the charge trap layer includes a first oxide layer, a nitride layer, and a second oxide layer, sequentially stacked on the side surfaces of the plurality of gate electrodes.

6. The semiconductor memory device according to claim 5, wherein the charge trap layer further includes an aluminum oxide layer disposed between the plurality of gate electrodes and the first oxide layer.

7. The semiconductor memory device according to claim 4,
wherein, in a first memory state, the information storage circuit is configured to receive a voltage applied between the plurality of gate electrodes and the first semiconductor layer, and
wherein, in a second memory state, the information storage circuit is configured to receive a voltage for driving the light emitting circuit applied between some of the plurality of gate electrodes and the first metal layer.

8. The semiconductor memory device according to claim 7,
wherein the plurality of gate electrodes include a mode control line gate electrode,
wherein the information storage circuit is configured to receive a voltage applied to the mode control line gate electrode in the first memory state, and
wherein the information storage circuit is configured to exclude the voltage applied to the mode control line gate electrode in the second state.

9. The semiconductor memory device according to claim 4, wherein the channel structure further includes an insulating layer disposed between the light emitting circuit and the substrate.

10. The semiconductor memory device according to claim 4, wherein the channel structure further includes a second semiconductor layer and an insulating layer that are disposed on the photodetection circuit and stacked sequentially on a side surface of the charge trap layer.

11. The semiconductor memory device according to claim 10, further comprising a bit line disposed on the channel structure,
wherein the bit line is electrically connected to the second semiconductor layer.

12. The semiconductor memory device according to claim 11,
wherein the plurality of gate electrodes include a string select line gate electrode, and
wherein the string select line gate electrode is positioned above an uppermost portion of the photodetection circuit and below a lowermost portion of the bit line.

13. The semiconductor memory device according to claim 1, wherein the information storage circuit includes a ferroelectric layer.

14. The semiconductor memory device according to claim 13, wherein the channel structure further includes an insulating layer disposed between the ferroelectric layer, the light emitting circuit, and the substrate.

15. The semiconductor memory device according to claim 13, wherein the channel structure further includes a semiconductor layer and an insulating layer that are disposed on the photodetection circuit and stacked sequentially on a side surface of the ferroelectric layer.

16. The semiconductor memory device according to claim 15, further comprising a bit line disposed on the channel structure,
wherein the bit line is electrically connected to the semiconductor layer.

17. The semiconductor memory device according to claim 1,
wherein the plurality of gate electrodes include a plurality of word line gate electrodes, and
wherein the photodetection circuit is configured to detect an intensity of light emitted from a region of the light emitting circuit associated with a selected word line gate electrode of the plurality of word line gate electrodes.

18. A semiconductor memory device, comprising:
a substrate;
a mold structure including a plurality of gate electrodes and a plurality of mold insulating layers, alternatively stacked on the substrate; and
a channel structure extending into the mold structure,
wherein the channel structure includes an information storage circuit, a light emitting circuit, and a metal layer, sequentially stacked on side surfaces of the plurality of gate electrodes.

19. An electronic system, comprising:
a main substrate;
a semiconductor memory device on the main substrate; and
a controller electrically connected to the semiconductor memory device on the main substrate,
wherein the semiconductor memory device includes:
a cell substrate;
a mold structure including a plurality of gate electrodes and a plurality of mold insulating layers, alternatively stacked on the cell substrate; and
a channel structure extending through the mold structure, and
wherein the channel structure includes an information storage circuit, a light emitting circuit, and a metal layer, sequentially stacked on side surfaces of the plurality of gate electrodes.

20. The electronic system according to claim 19,
wherein the channel structure further includes a photodetection circuit disposed on the metal layer,
wherein the photodetection circuit is configured to detect light emitted from the light emitting circuit, and
wherein a level of the light detected by the photodetection circuit is indicative of a memory state of the information storage circuit.
